(19) United States
(12) Patent Application Publication
(10) Pub. No.: US 2011/0205787 A1
(43) Pub. Date: Aug. 25, 2011

(54) DUAL-RAIL SRAM WITH INDEPENDENT READ AND WRITE PORTS

(75) Inventors: Roelof Herman Willem Salters, Waalre (NL); Tobias Sebastiaan Doorn, Eindhoven (NL); Luis Elvira Villagra, Maastricht (NL)

(73) Assignee: NXP B.V., Eindhoven (NL)

(21) Appl. No.: 13/124,733

(22) PCT Filed: Oct. 12, 2009
(86) PCT No.: PCT/IB09/54464

§ 371 Date: Apr. 18, 2011

(30) Foreign Application Priority Data
Oct. 22, 2008 (EP) 08167230.5

(51) Int. Cl. G11C 11/412

(52) U.S. Cl. 365/154

(57) ABSTRACT

A Static Random Access Memory comprising a matrix arrangement of cells, each cell comprising:—a bistable loop of a first inverter and a second inverter, in which an input of the first inverter is coupled to an output of the second inverter at a first bistable node and an input of the second inverter is coupled to an output of the first inverter at a second bistable node;—a first access transistor connected between the first bistable node and a write bitline, the first access transistor having a control terminal connected to a write wordline, and—a second access transistor connected between the second bistable node and a line being the complement of the write bitline, the second access transistor having a control terminal connected to the write wordline wherein—a first separate read port is connected between a read bitline and a source potential, which first read port has at least two control terminals, one control terminal being connected to the second bistable node and one to a read wordline, and—a second separate read port is connected between a line being the complement of the read bitline and a source potential, which second read port has at least two control terminals, one control terminal being connected to the first bistable node and one to the read wordline. At least one of the read ports can comprise two series-connected transistors, which may have mutually different threshold voltages.

### FIELD OF THE INVENTION

The invention relates to the field of volatile memory devices and particularly to Static Random Access Memories (SRAMs).

In particular, the invention relates to a Static Random Access Memory comprising a matrix arrangement of cells, each cell comprising:
a bistable loop of a first inverter and a second inverter, in which an input of the first inverter is coupled to an output of the second inverter at a first bistable node and an input of the second inverter is coupled to an output of the first inverter at a second bistable node;
a first access transistor connected between the first bistable node and a write bitline, the first access transistor having a control terminal connected to a write wordline, and
a second access transistor connected between the second bistable node and a line being the complement of the write bitline, the second access transistor having a control terminal connected to the write wordline.

In addition the invention relates to a method of reading, as well as to a method of writing, the value of a bistable node of a cell of such a Static Random Access Memory.

Furthermore the invention relates to a method of operating a Static Random Access Memory as described hereabove, whereby use is made of a so-called dual-rail architecture.

### BACKGROUND OF THE INVENTION

An SRAM is a type of volatile memory. This means that the memory cells of the memory retain their data as long as power to the cells remains applied, but that the data will eventually be lost when the memory cells are not powered any more. An SRAM cell typically makes use of four transistors forming a bistable latching circuit by cross-coupling two inverters, each built out of two transistors. This bistable latching circuit has two stable states: one stable state can be used to represent, and so store, a logical “0”, and the other stable state can be used to represent a logical “1”. In general, next to these four transistors (also referred to as the “kernel” of the cell), two other transistors are used as access transistors, which access transistors serve to control the access to the bistable latching circuitry during read or write operations from/to that circuitry. Although it is possible to build an SRAM cell out of five transistors (also called a “5T-cell”)—four for the two cross-coupled inverters and one as an access transistor for access to the bistable circuitry—the most common SRAM cell is currently built out of six transistors (also called a “6T-cell”), in which two transistors serve as access transistors. The bistable latching circuitry can then, via the access transistors, be connected to a bitline and to a line on which the inverse of the bitline is present, respectively. The line on which the inverse of the bitline is present—also called the bitline's complement—is usually made available because the connection of such a bistable latching circuit to the bitline and its complement allows a higher noise margin. The traditional 6T-SRAM cell makes use of four nMOS transistors and two pMOS transistors, created in known CMOS-processes. The SRAM cells are powered by an internal or external power supply, which can be used to apply a potential difference across the SRAM cells.

An SRAM cell can be in a read mode, a write mode or a sleep mode, also known as standby mode. In the read mode, the stored information in the cell is read by reading out the state of the bistable circuit, whereas, in the write mode, the bistable circuit assumes one of the above-mentioned two states, as dictated by the information which has to be stored. The SRAM cell is in a sleep mode when the access transistors essentially do not allow access to the bistable circuitry.

Because of the nature of the SRAM cells and their use of two cross-coupled inverters, stored information will only be retained in the cells as long as there is some minimal voltage, also called minimal retention voltage, across these cells. The minimal retention voltage strongly depends on technological parameters of the SRAM design, as well as on factors such as temperature. Moreover, in an array of SRAM-cells, one has to assure that all the cells have (at least) the minimal retention voltage across them under all circumstances; in order to ensure this, one has to take into account the worst possible scenario (e.g. as regards temperature)—as a result of which, a lot of the time, the total applied voltage will be higher than is necessary. This, in turn, means that, a lot of the time, there will be a (much) higher-than-necessary leakage current flowing through the memory as a whole. It is said required minimal retention voltage that, in practice, does not allow the SRAM memory cell according to the prior art to be used below a certain threshold power, as a result of which there is also an undesirable lower limit to the energy consumed by the memory. This is a major disadvantage of the prior-art SRAM memory cell design.

In the SRAM memory cell according to the prior art, the access transistors are directly coupled between the outputs of the two inverters and the bitline or its complement. During read mode, there can be a substantial disturbance of the stored information in the bistable latching circuit, as a read current flows directly to or from an output node of the bistable circuit from or to the bitline or its complement, thereby possibly disturbing the stable state that the memory cell is in. The SRAM memory of the prior art has to be carefully designed to take into account the worst possible circumstances during read mode, such that no stored data will be lost because of a read operation—in other words, designed such that a stable status of the bistable latching circuit will not be changed because of a read operation. The possible disturbance of the stored data in the memory cell, and the requirement that, in designing the memory cell, one should carefully make allowances for the worst possible disturbance, is another disadvantage of the design of an SRAM memory cell according to the prior art.

Yet another disadvantage of the current SRAM design becomes apparent when one takes a look at its practical applications. In practice, an SRAM memory will often be used in cooperation with other components—for example in a so-called “System on Chip” (SoC or SOC). In such an SoC, the components of an electrical system are all integrated into a single Integrated Circuit (IC), and there are often one or more memories present in such an IC. When one uses a prior-art SRAM as a memory, one cannot lower the power supply to the IC as a whole, because of the required minimal retention voltage of the memory cells: after all, the SRAM memory cells will not function properly if they are powered with a voltage lower than this minimal retention voltage. So, one typically cannot lower the energy dissipation of the SoC as a whole if it comprises an SRAM memory according to the prior art. This is a major disadvantage of the conventional SRAM design.

### SUMMARY OF THE INVENTION

It is an object of the invention to address the aforementioned disadvantages.

In particular, it is an object of the invention to lower the energy use of an SRAM memory as a whole.

It is another object of the invention to enable an SRAM to interface with other components making use of a voltage power supply lower than or equal to the nominal voltage used as power supply for the first and second inverters of the cells in said SRAM.

Moreover, it is an object of the invention to enable an SoC comprising an SRAM memory to be used at a voltage power supply level lower than or equal to the nominal voltage used as power supply for the first and second inverters of the SRAM's cells.

Yet another object of the invention is to diminish the potential read disturbance of an SRAM memory cell during a read operation.

These and other objects are achieved in an Static Random Access Memory as set forth in the second opening paragraph above, characterized in that:
a first separate read port is connected between a read bitline and a source potential, which first read port has at least two control terminals, one control terminal being connected to the second bistable node and the other to a read wordline; and
a second separate read port is connected between a line being the complement of the read bitline and the source potential, which second read port has at least two control terminals, one control terminal being connected to the first bistable node and the other to the read wordline.

The invention is based on the insight that the use of separate read ports, each having one control terminal connected to a bistable node of said two inverters, together with the use of separate readlines and writelines, will make high-performance (i.e. high-speed) dual-rail operation of the memory cell possible, while at the same time minimizing the read disturbance during a read operation. While the memory cell itself can be driven at a nominal voltage, the periphery of the memory cell (i.e. all the electronic circuitry of the memory besides the cells of the memory array) can be driven at a voltage level lower than or equal to said nominal voltage.

In one embodiment of the invention, at least one read port comprises two transistors connected in series. An advantage of this embodiment is that such a read port is quite easy to make during the same process steps used to make the 4T kernel of the memory cell.

In a further embodiment of the invention as alluded to in the previous paragraph, said at least one read port comprises:
a first transistor, having a control terminal connected to a bistable node (of the bistable latching circuit);
a second transistor, having a control terminal connected to the read wordline, whereby the threshold voltage of said first transistor is higher than that of said second transistor. In this advantageous embodiment of the invention, the higher threshold voltage of said first transistor ensures a low leakage current during the non-active mode of the read port, while the lower threshold voltage of said second transistor ensures a reasonable read current—flowing through the read port—at a low read bitline and low read wordline voltage. Such a configuration of the read port in which said first transistor has a higher threshold voltage also enables a high read current, as the control terminal of this transistor is connected to the kernel of the memory cell, which is driven by the nominal voltage.

In yet a further embodiment of the present invention, each of the first inverter and the second inverter of the bistable loop comprises two transistors. In this embodiment of an inverter, an energy dissipating resistor—through which a current is constantly flowing—does not have to be present, which allows reduced energy consumption to be realized.

In another embodiment of the present invention, an inverter of the bistable loop comprises a pull-up transistor and a pull-down transistor. An advantage of this embodiment is that use can be made of the standard 4T kernel used in the current SRAM design, i.e. two pMOS transistors as pull-up transistors and two nMOS transistors as pull-down transistors. If, for each inverter, use is made of two complementary transistors, the energy use of such an inverter will be minimal since, in both the bistable states of the bistable loop, one of the two transistors will be off.

Another aspect of the present invention relates to an electronic apparatus comprising a Static Random Access Memory as set forth in claim 1. Such an apparatus may be relatively small/fundamental—such as an (SoC) IC—or may be relatively large/compound—such as a computer, computer peripheral (e.g. a printer, scanner, or data storage device), audio device, video device, wireless communication device, etc. As elucidated above, use of an SRAM according to the invention in such an apparatus allows the electrical power consumed by the apparatus to be reduced, since the circuitry surrounding the SRAM can, in principle, be operated at a voltage that is no longer dictated by the SRAM's minimum retention voltage.

The invention further provides a method of reading a value of a bistable node of a memory cell of a Static Random Access Memory as set forth in claim 1, said method being characterized by the steps of:
deactivating the access transistors with the aid of the write wordline;
activating the read ports with the aid of the read wordline connected to one of the control terminals of the read ports, using a voltage on the read wordline that is lower than or equal to the nominal voltage used as power supply for the first and second inverters;
conducting a read current through the read ports, thereby charging or discharging the read bitline and the line being the complement of the read bitline that are connected to the read ports.

The invention also provides a method of writing a value of a bistable node of a memory cell of a Static Random Access Memory as set forth in claim 1, said method being characterized by the steps of:
deactivating the read ports with the aid of the read wordline;
activating the access transistors with the aid of the write wordline connected to the control terminals of the access transistors, using a voltage on the write wordline that is lower than or equal to the nominal voltage used as power supply for the first and second inverters;
conducting a write current through the access transistors, thereby charging or discharging the bistable nodes connected to the access transistors.

The invention further provides a method of operating a Static Random Access Memory as claimed in claim 1, whereby use is made of a dual-rail architecture. In contrast to a single-rail architecture—where, in a system comprising electrical circuitry, only one power supply voltage, on a single rail, is made available to power said circuitry—a dual-rail architecture provides two power supply voltages, available on two separate rails. These two supply voltages may have the same or different values. Use of the same voltages is often contemplated when one wants to separate possible voltage irregularities caused by one portion of electrical circuitry from influencing the voltage supply to another portion of circuitry. A dual-rail power supply (also called a split power supply) in which the two voltages have the same value may also occur when use is made of dynamic voltage scaling, in which one employs an adjustable (tracking) voltage supply. The structure of the Static Random Access Memory of the present invention allows operation of the memory using a dual-rail architecture: the 10T-cells of the memory may be operated from one of the rails at a nominal voltage, while the periphery of the memory cells (see above) may be operated from the other rail at a voltage level lower than or equal to said nominal voltage.

### BRIEF DESCRIPTION OF THE DRAWINGS

In the following section, the invention will be described with reference to the attached schematic drawings, in which:

FIG. 1 depicts a prior-art SRAM.

FIG. 2 depicts an embodiment of the present invention.

In the Figures, like reference numerals are used to indicate like features.

### DETAILED DESCRIPTION OF EMBODIMENTS

### Background Art

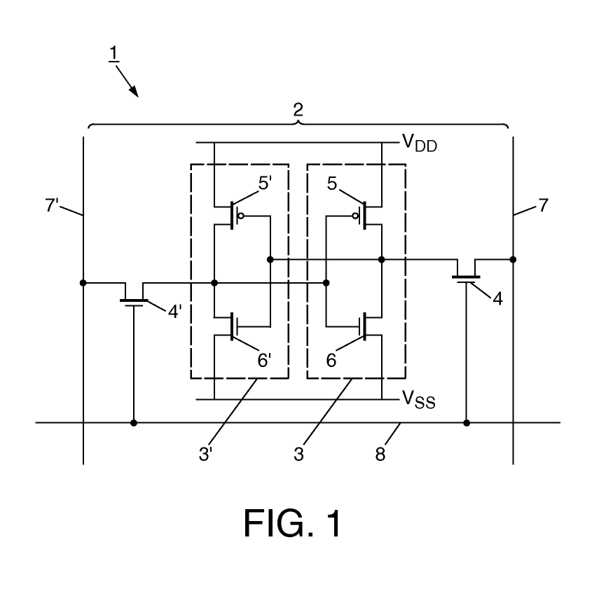

With reference to FIG. 1, part of a prior-art SRAM 1 comprising a matrix arrangement of memory cells 2 arranged in rows and columns is schematically shown. SRAM 1 is currently frequently embodied as embedded memory, and can have any size suitable for the application in which it is used. At present, memory sizes ranging from a couple of kilobits to 240 Mbit exist. An SRAM memory cell 2 is typically comprised of a bistable latching element (loop) built out of two cross-coupled inverters 3, 3′ and one or more access transistors 4, 4′. A cross-coupled inverter 3/3′, in its turn, is typically built out of two transistors 5, 6/5′, 6′. A bistable latching element (3+3′) has two stable states in which it can reside, as long as it is connected to an appropriate power supply; it is therefore possible to store a bit of information in the latching element by forcing it into one of its stable states, representing either a logical “0” or a logical “1”. The bistable latching element (3+3′) is connected to a bitline 7 through at least one access transistor 4, whereby, in general, the access transistor 4 is also connected to a writeline 8, which writeline 8 can be given a voltage level that determines whether the access transistor 4 connects the latching element to said bitline 7 or not. The writeline 8 is also often called a wordline, as it allows a word of, for instance, 8 bits wide in an 8-bit wide SRAM, to be written or read in a write or read cycle, respectively. Connection of the latching element (3+3′) to a bitline 7 is necessary so as to read out information stored in the latching element during read mode or to store a bit of information into the latching circuit (loop) during write mode: the information present in the memory cell 2 will be put on the bitline 7 during the read mode, whereas the information to be stored into the memory cell 2 will be put on the bitline 7 during write mode. Theoretically, it would be enough to connect the two cross-coupled inverters 3, 3′ to only one bitline 7 with only one access transistor 4; however, in practice, two access transistors 4, 4′ are used, one for connecting the bistable element to the bitline 7 itself and the other for connecting the bistable element to another line 7′, namely the bitline's complement line. On this latter line 7′, the inverse value of the value on the bitline 7 is present. The reason for using these two access transistors 4, 4′ connected to the bitline 7 and its complement 7′ is that such an arrangement improves the noise margin. Therefore, the six-transistor SRAM memory cell 2 (also called “6T-cell”)—with two access transistors 4, 4′ and four transistors 5, 6, 5′, 6′ for the two cross-coupled inverters 3, 3′—is the most currently used SRAM cell 2. The transistors used may, for example, be bipolar junction transistors, or Metal Oxide Semiconductor Field Effect Transistors (MOSFETs). The use of MOSFET transistors in an SRAM cell is very common today, as such transistors can be made in Complementary Metal Oxide Semiconductor (CMOS) technologies, which are at present commonly used in the semiconductor industry. Another reason why MOSFETs are often used is that they generally consume less power than transistors of the bipolar junction field type.

As the SRAM 1 is a volatile memory, it has to be connected to a power supply, even if it is in sleep mode, which is also called the standby mode; accordingly, prior-art SRAMs are connected (in all modes) to a voltage supply, which is depicted in FIG. 1 by (the voltage difference between) voltage lines V_{DD} and V_{SS}. At present, SRAMs made in CMOS are powered by a voltage difference of about 0.9 to 3.3 Volt, mostly depending on the age of the employed technology: the newer the technology, the lower the voltage differences that are necessary. The SRAM memory cells 2 will draw current according to their design specifics and status. During sleep mode, for instance, the current drawn by the SRAM 1 will be the sum of the leakage currents of the memory cells 2 in the SRAM. These leakage currents depend, for example, on the employed technology, applied voltage difference, design choices, and, even more importantly, on temperature and threshold voltage (in which latter two cases there is an exponential dependence

### Embodiment of the Present Invention

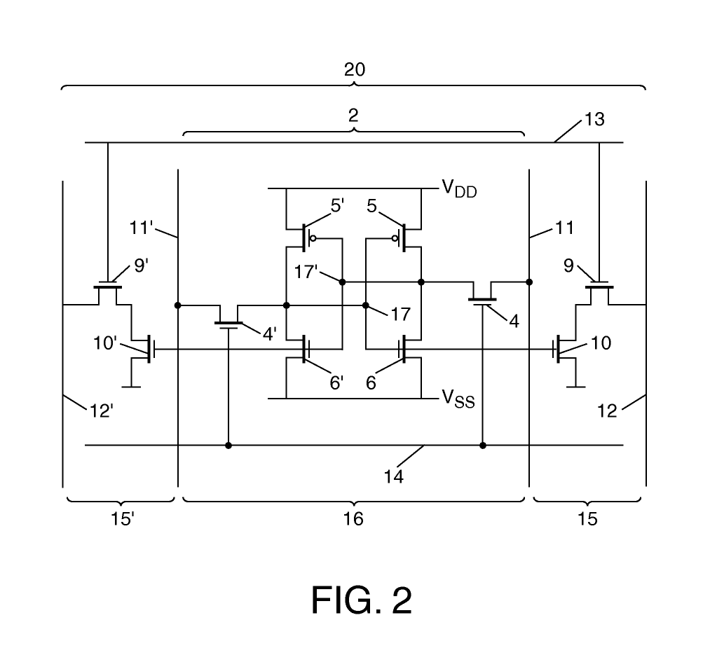

FIG. 2 depicts an embodiment of the present invention. A 6T structure 2 as set forth above is present, but now two read ports 9, 10/9′, 10′ are added. FIG. 2 also shows a separate read bitline 12 and its complement 12′, a separate write bitline 11 and its complement 11′, as well as a write wordline 14 and a read wordline 13.

In the depicted embodiment, use is made of a differential, symmetric memory cell design. This is advantageous in that the same sense amplifier as currently used in conventional 6T-memory cell arrangements can also be used in the present setup; if use were to be made of a single-ended (asymmetric) memory cell with only one read/write port, one would have to use a different sense amplifier (FIG. 2 does not depict a sense amplifier, but the skilled artisan will be familiar with this device, and will appreciate how it is to be connected and employed). Of course, the depicted differential, symmetric memory cell arrangement allows faster reading of the information stored in the memory cell, as a full discharging of the single bitline—which is often necessary in a single-ended memory cell—is not necessary in a differential memory cell.

The 4T kernel 16 of the depicted SRAM memory cell 20 is still connected to a voltage supply (depicted in FIG. 2 by a voltage difference between voltage lines V_{DD} and V_{SS}), but now the invention allows the periphery of the memory cell 20 (see above) to be driven at a lower or equal “periphery voltage”. Again, the employed power supply for the kernel 16 (comprising the four transistors 5, 5′, 6, 6′, forming the two cross-coupled inverters), depends on the technology used, but it has to deliver a minimal voltage that is dictated by the required minimal retention voltage of the kernel 16, as discussed above. In a standard prior-art 6T memory cell, the required minimum retention voltage during sleep mode differs from the minimum retention voltage during read or write mode (collectively referred to as “active mode”)—the former retention voltage generally being much lower than the latter. However, in the SRAM memory cell according to the invention, this is no longer the case: the required minimum retention voltage in both the sleep and the active mode is the same.

One also has to take into account the stability of selected memory cells 20 during read mode, which will generally decrease when use is made of a lower-voltage power supply. Therefore, to guarantee the functionality of active memory cells 20, one can adopt a general design rule for the minimal voltage supply for the kernel 16 of about the nominal voltage for the employed technology minus a 10% margin (a power management system is assumed to supply a voltage within 10% of the specified value.) The nominal voltage in a 65 nanometer (65 nm) CMOS-process is, for instance, at present 1.2 V, so that the minimal voltage supply for the kernel 16 in such a CMOS process would be 1.08 V according to said design rule. In another commonly used CMOS-process—the 45 nm CMOS process—the nominal voltage supply is at present 1.1 V, so that the minimal voltage supply for the SRAM kernel 16 in this case would be 0.99 V according to said design rule.

The signals coming from the periphery on the other hand (i.e. the voltage signals on the read wordline 13, the write wordline 14, the read bitline 12 and the write bitline 11, as well as their various complements, where applicable) can, according to the invention, be lower then the required minimal voltage supply for the kernel 16; for said periphery, one could, for example, use a voltage supply of about 0.8 V. Depending on the design parameters of the components of the circuits involved, even lower voltages—down to half of the nominal voltage supply—could possibly be used.

The lowering of the voltages needed for the periphery of the 10T cell 20 is made possible by the presence of the separate read ports 15, 15′ as well as the use of separate readlines 12, 12′, 13 and writelines 11, 11′, 14. The lowered voltages on the wordlines 13, 14 and bitlines 11, 11′/12, 12′ may lead to energy savings for the memory array as a whole. In practice, the voltage value used on the bitlines 11, 12/11′, 12′ will also be a matter of design choice: an SRAM optimized for low power consumption can have a lower voltage value on the bitlines, whereas, if speed is more important, a higher voltage value can be used on the bitlines.

According to one embodiment of the invention, each read port 15, 15′ comprises two (series-connected) transistors 9, 10/9′, 10′, in which a first transistor 10/10′ (connected to the relevant one of the bistable nodes 17, 17′ of the kernel 16) has a higher threshold voltage than the other (second) transistor 9/9′ (connected to the read wordline 13). The presence of the first transistor 10/10′ with a high threshold voltage ensures that there is not much leakage of current through its respective read port during write or standby mode, and, on the other hand, the use of the second transistor 9/9′ with a low threshold voltage guarantees a reasonable read current during read mode with a lowered voltage on the read wordline 13. One could, for example, choose the threshold voltage of the second transistor 9/9′ to be about 200 millivolt lower than that of the first transistor 10/10′, though the invention certainly allows other differences to be chosen. As an example, in the 45 nm CMOS process technology, the high voltage threshold might be between about 450 millivolt (450 mV) and 550 mV, whereas the low threshold voltage might be between about 280 mV and 380 mV.

A reasonably high read current in the microampere range during read mode is also enabled by the higher gate voltage on the transistor 10/10′ with a high threshold voltage, as the gate of this transistor is connected to the 4T kernel 16, which is driven by the normal (nominal) voltage supply for the kernel.

According to the invention, each read port 15, 15′ is connected to the gate of a respective pull-down transistor 6, 6′ of the bistable element; in this manner, there is much less influence on the states of the bistable nodes 17, 17′ of the kernel 16 during read mode, thus diminishing the risk of read-related disturbance of these nodes. Because of this connection of the read ports to the kernel 16, it becomes possible to make the pull-down transistors 6, 6′ a little smaller, since a lower (static) noise margin will now suffice.

During write mode, the access transistors 4, 4′ of the present invention can now be activated with the aid of the write wordline 14 connected to the control terminals of said access transistors, using a voltage on the write wordline 14 that is lower than or equal to the nominal voltage used as power supply for the first and second inverters in the kernel 16. When a lower voltage is used on the write wordline 14, the access transistors 4, 4′ of the present invention will have to be larger than currently used access transistors, as the access transistors will now have a more limited drive strength to write information to the kernel 16 of the memory cell 20.

In the prior art, the presence of SRAMs on an SoC typically precludes the use of a lower voltage supply for that SoC. However, the present invention allows an SRAM to interface with an SoC via a lower voltage power supply. This can lead to a significant reduction of power consumption by the SoC as a whole. At present, the (digital) components of an SoC other then the memories account for about 80% of the total power consumption of the SoC. If one only considers these components and one were to lower the voltage power supply to half of the voltage power supply that is conventionally used, the power consumption of these components would be lowered to a quarter of its previous value, as the dominant component of power consumption is proportional to the square of the voltage used. Of course, there will also be a reduction of the power consumption of the employed SRAMs, as, according to the invention, the periphery of the 10T SRAM memory cell 20 can be driven at a lower voltage level.

Although preferred embodiments of the memory and methods of the present invention have been illustrated in the accompanying drawings and described in the foregoing detailed description, it should be understood that the invention is not limited to the embodiments disclosed, but is capable of numerous rearrangements, modifications, and substitutions without departing from the spirit of the invention as set forth and defined by the following claims. The skilled person will, for example, understand that it may be possible to further lower the voltage supply to the kernel, although this may lead to an attendant reduction in speed. In addition, it will also be immediately clear to the skilled artisan that the source potential to which a read port is connected may be the voltage VSS, but may also be another source potential, uncluding earth. Moreover, it will also be immediately clear that the scope of the present invention is not limited to the use of the same maximal (perifery) voltage level on the the read wordline, the write wordline, the read bitlines and the write bitlines; for instance, so as to facilitate an easier write operation, one could boost the voltage level on the write wordline using bootstrapping techniques know in the art. Falling within the scope of the invention is also the use of a levelshifter between the periphery and the memory matrix, causing different voltage levels on the respective word- and bitlines.

1. A Static Random Access Memory having a matrix arrangement of cells, each cell comprising:
a bistable loop of a first inverter and a second inverter, in which an input of the first inverter is coupled to an output of the second inverter at a first bistable node and an input of the second inverter is coupled to an output of the first inverter at a second bistable node;
a first access transistor connected between the first bistable node and a write bitline, the first access transistor having a control terminal connected to a write wordline,
a second access transistor connected between the second bistable node and a line being the complement of the write bitline, the second access transistor having a control terminal connected to the write wordline,
a first separate read port connected between a read bitline and a source potential, which said first read port has at least two control terminals, one control terminal being connected to the second bistable node and one to a read wordline, and
a second separate read port connected between a line being a complement of the read bitline and a source potential, which said second read port has at least two control terminals, one control terminal being connected to the first bistable node and one to the read wordline.

2. A Static Random Access Memory according to claim 1, wherein at least one read port comprises two transistors connected in series.

3. A Static Random Access Memory according to claim 2, wherein said at least one read port comprises:
a first transistor, having a control terminal connected to a bistable node; and
a second transistor, having a control terminal connected to the read wordline, whereby the threshold voltage of said first transistor is higher than that of said second transistor.

4. A Static Random Access Memory according to claim 1, wherein the first inverter and the second inverter of the bistable loop each comprises two transistors.

5. A Static Random Access Memory according to claim 4, wherein an inverter of the bistable loop comprises a pull-up transistor and a pull-down transistor.

6. An electronic apparatus comprising a Static Random Access Memory as claimed in claim 1.

7. A method of reading a value of a bistable node of a Static Random Access Memory cell of a Static Random Access Memory according to claim 1, comprising the steps of:
deactivating the access transistors using the write wordline,
activating the read ports using the read wordline connected to one of the control terminals of the read ports, with a voltage on the read wordline that is lower than or equal to the nominal voltage used as power supply for the first and second inverters, and
conducting a read current through the read ports, thereby charging or discharging the read bitline and the line being the complement of the read bitline that are connected to the read ports.

8. A method of writing a value of a bistable node of a Static Random Access Memory cell of a Static Random Access Memory according to claim 1, comprising the steps of:
deactivating the read ports using the read wordline,
activating the access transistors using the write wordline connected to the control terminals of the access transistors, with a voltage on the write wordline that is lower than or equal to the nominal voltage used as power supply for the first and second inverters, and
conducting a write current through the access transistors thereby charging or discharging the bistable nodes connected to the access transistors.

9. A method of operating a Static Random Access Memory as claimed in claim 1, whereby use is made of a dual-rail architecture.
